(19) United States
(12) Patent Application Publication
(10) Pub. No.: US 2026/0021535 A1
(43) Pub. Date: Jan. 22, 2026

(54) COATED TOOL AND CUTTING TOOL

(71) Applicant: KYOCERA CORPORATION, Kyoto-shi, Kyoto (JP)

(72) Inventors: Naohisa MATSUDA, Satsumasendai-shi, Kagoshima (JP); Tomoya AMAMI, Satsumasendai-shi, Kagoshima (JP); Akihiro KATSUMARU, Satsumasendai-shi, Kagoshima (JP)

(21) Appl. No.: 18/869,281

(22) PCT Filed: May 1, 2023
(86) PCT No.: PCT/JP2023/017031

§ 371 Date: Nov. 26, 2024

(30) Foreign Application Priority Data
May 27, 2022 (JP) 2022-086717

(51) Int. Cl. B23B 27/14; C22C 29/08

(52) U.S. Cl. CPC B23B 27/148; C22C 29/08; B23B 2222/28; B23B 2228/10

(57) ABSTRACT

A coated tool in a non-limiting embodiment of the present disclosure includes a base and a coating layer located on a surface of the base. The base includes a hard phase including W and C, a solid solution phase including W, C, and Ti, and a binding phase including an iron group metal. A residual stress of the hard phase in the base is “a,” and the “a” is in a range of −2.5 to −0.2 GPa. A residual stress of the hard phase in the surface of the base is “b,” and the “b” is in a range of −2.0 to 0.0 GPa.

### CROSS-REFERENCE TO RELATED APPLICATION

The present application claims priority to Japanese Patent Application No. 2022-086717, filed May 27, 2022. The contents of this application are incorporated herein by reference in their entirety.

### TECHNICAL FIELD

The present disclosure relates to a coated tool and a cutting tool.

### BACKGROUND

Cemented carbide including WC (tungsten carbide) as a hard phase is used for a base, etc. in a coated tool, and is applied to a cutting tool, such as an end mill. For example, Japanese Patent 3424263 (Patent Document 1) describes that peeling in an interface between a base and a coating layer can be avoided as long as a residual stress of the hard phase in a base material is in a range of −0.5 to 0 GPa, and a residual stress in the coating layer is −0.2 to 0.2 GPa.

Patent Document 1 also describes that a coefficient of heat expansion of the coating layer becomes larger than that of the base material by coating the cemented carbide, and therefore tensile stress often remains in the coating layer after completion of the coating, and fracture resistance is lowered by the coating. Patent Document 1 makes no mention of sintering conditions, such as cooling rate.

### SUMMARY

A coated tool in a non-limiting embodiment of the present disclosure includes a base and a coating layer located on a surface of the base. The base includes a hard phase including W and C, a solid solution phase including W, C, and Ti, and a binding phase including an iron group metal. A residual stress of the hard phase in the base is “a.” The “a” is in a range of −2.5 to −0.2 GPa. A residual stress of the hard phase in the surface of the base is “b.” The “b” is in a range of −2.0 to 0.0 GPa.

A cutting tool in a non-limiting embodiment of the present disclosure includes a holder that extends from a first end toward a second end and includes a pocket on a side of the first end, and the coated tool located in the pocket.

### BRIEF DESCRIPTION OF THE DRAWINGS

FIG. 1 is a perspective view illustrating a coated tool in a non-limiting embodiment of the present disclosure;

FIG. 2 is a sectional view illustrating a neighborhood of a surface of the coated tool illustrated in FIG. 1; and

FIG. 3 is a perspective view illustrating a cutting tool in a non-limiting embodiment of the present disclosure.

### EMBODIMENT

### <Coated Tool>

A coated tool 1 in a non-limiting embodiment of the present disclosure is described in detail below with reference to the drawings. For the convenience of description, the drawings referred to below illustrate, in simplified form, only main members necessary for describing embodiments. Hence, the coated tool 1 may include any arbitrary structural member not illustrated in the drawings referred to. Dimensions of the members in the drawings faithfully represent neither dimensions of actual structural members nor dimensional ratios of these members. These points are also true for a cutting tool described later.

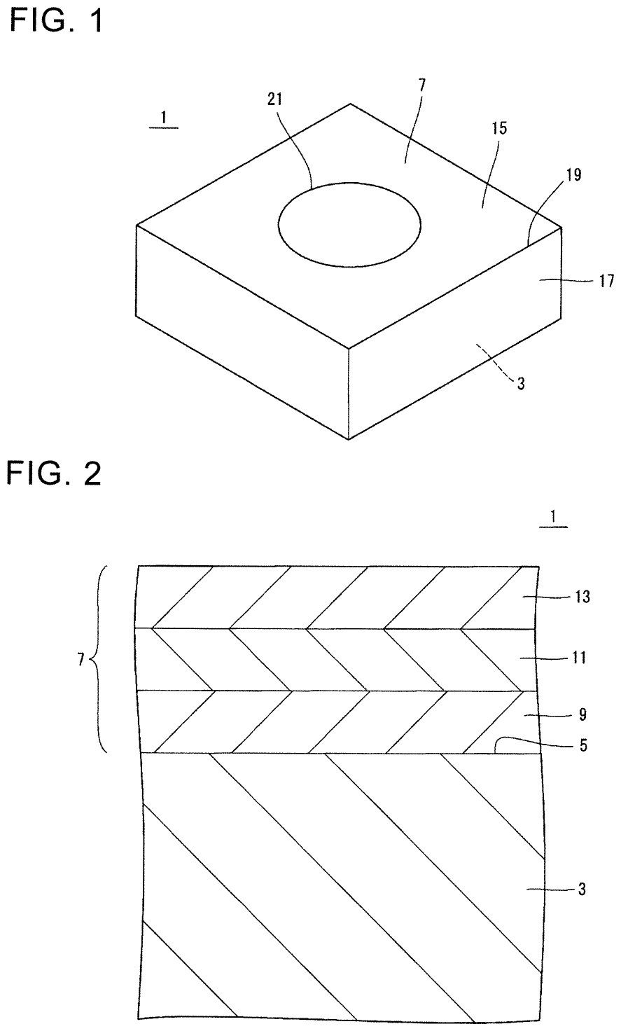

The coated tool 1 may include a base 3 and a coating layer 7 located on a surface 5 of the base 3 as in a non-limiting embodiment illustrated in FIGS. 1 and 2.

The base 3 may include a hard phase, a solid solution phase, and a binding phase.

The hard phase may include W (tungsten) and C (carbon). In other words, the hard phase may include WC. The hard phase may include WC as a main component. The term “main component” as used herein may mean a component having the largest value of percent by mass compared to other components. Specifically, components having top two values of percent by mass among the components included in the hard phase may be W and C.

The solid solution phase may include W, C, and Ti (titanium). The solid solution phase may include W, C, and Ti as a main component. That is, a total value of percent by mass each of W, C, and Ti may be largest in the solid solution phase. Components having top three values of percent by mass among the components included in the solid solution phase may be W, C, and Ti.

The binding phase may include an iron group metal. Examples of the iron group metal may include Co (cobalt) and Ni (nickel). The binding phase may include at least one of Co and Ni. The binding phase may include the iron group metal as a main component. The binding phase is servable as a phase that bonds the hard phases adjacent to each other.

Individual compositions of the hard phase, the solid solution phase, and the binding phase may be measured with, for example, Energy-Dispersive X-ray Spectroscopy (EDS). Measurements may be made using an EDS included in an electron microscope. Examples of the electron microscope may include Scanning Electron Microscope (SEM) and Transmission Electron Microscope (TEM). For example, measurement conditions of the EDS may be set as follows:
Acceleration voltage: 20 kV
Beam diameter: 12 to 15 (Counts detected by an apparatus are adjusted to 20000 or more)

Here, a residual stress of the hard phase in the base 3 may be “a.” The “a” may be in a range of −2.5 to −0.2 GPa. A residual stress of the hard phase in the surface 5 of the base 3 may be “b.” The “b” may be in a range of −2.0 to 0.0 GPa. If the residual stresses in the interior of the base 3 and in the surface 5 of the base 3 are respectively in the above ranges, it is easy to improve adhesion strength between the base 3 and the coating layer 7, and it is easy to avoid peeling between the base 3 and the coating layer 7. In other words, it becomes possible to reduce the peeling between the two. Therefore, the coated tool 1 has high wear resistance.

The term “in the base” as used herein may mean the interior of the base 3. Specifically, the interior of the base 3 which is 0.05-2 mm away from the surface 5 of the base 3 may be “in the base.”

The residual stress may be a compressive stress. If a residual stress has a negative value, the residual stress is the compressive stress. The residual stress may be measured by sin 2ψ method using an X-ray stress measurement device (X-Ray Diffraction (XRD)). For example, measurement conditions may be set as follows:
Radiation Source: CuK
Output: 50 kV, 1000 μA
Collimator diameter: 0.5 mmϕ
Measurement method: 2D method

The “a” may be in a range of −1.3 to −0.5 GPa. In this case, it is easier to avoid the peeling between the base 3 and the coating layer 7. If the “a” is in the range of −1.3 to −0.5 GPa, a composition of the base 3 may include Nb (niobium). The base 3 may also include a β phase. The Nb may be included in the β phase or the binding phase or both of them. The β phase may be a composite carbide including at least one of Ti, Nb, Ta (tantalum) and Zr (zirconium), and W. For example, a composition of the β phase may be measured by the EDS.

The “b” may be in a range of −0.6 to −0.2 GPa. In this case, it is easier to avoid the peeling between the base 3 and the coating layer 7. If the “b” is in the range of −0.6 to −0.2 GPa, the composition of the base 3 may include Nb. The base 3 may also include a β phase. The Nb may be included in the β phase or the binding phase or both of them.

A ratio of “a” to “b” (a/b) may be 1.2 or more. In this case, it is easy to avoid crack propagation by holding the residual stress up to the interior of base 3. Therefore, it is easy to improve the adhesion strength between the base 3 and the coating layer 7. If used for a cutting tool, it is easy to improve cutting performance, such as intermittent performance.

The ratio of “a” to “b” (a/b) may be 2.1 or more. In this case, it is easier to improve the adhesion strength between the base 3 and the coating layer 7. An upper limit value of the ratio (a/b) may be 2.5. If the ratio (a/b) is 2.1 or more, the composition of the base 3 may include Nb. The base 3 may also include the β phase. The Nb may be included in the β phase or the binding phase or both of them.

The coating layer 7 may be located on the whole or a part of the surface 5 of the base 3. That is, the coating layer 7 may be located on at least the part of the surface 5 of the base 3.

The coating layer 7 may be deposited by Chemical Vapor Deposition (CVD) method. In other words, the coating layer 7 may be a CVD film. Alternatively, the coating layer 7 may be a PVD film deposited by Physical Vapor Deposition (PVD) method.

The coating layer 7 may be configured with a single layer, or may be configured with a plurality of laminated layers. Examples of composition of the coating layer 7 may include TiCN (titanium carbonitride), Al₂O₃ (alumina), and TiN (titanium nitride).

The coating layer 7 may include a first layer 9, a second layer 11, and a third layer 13 from a side of the base 3 as in the non-limiting embodiment illustrated in FIG. 2. The first layer 9 may include TiCN. The second layer 11 may include Al₂O₃. The third layer 13 may include at least one of TiN and TiCN.

The first layer 9 may include TiCN as a main component. The second layer 11 may include Al₂O₃ as a main component. The third layer 13 may include at least one of TiN and TiCN as a main component. The first layer 9 may be in contact with the base 3. The second layer 11 may be in contact with the first layer 9. The third layer 13 may be in contact with the second layer 11.

The coating layer 7 is not limited to having a specific thickness. A thickness of the first layer 9 may be set to, for example, approximately 5-20 μm. A thickness of the second layer 11 may be set to, for example, approximately 2-15 μm. A thickness of the third layer 13 may be set to, for example, approximately 0.1-20 μm. The thickness of the coating layer 7 may be measured by a cross-sectional observation using an electron microscope. The thickness of the coating layer 7 may be an average value. For example, the thickness may be measured at 10 or more measuring points at 1 μm intervals with a width of 10 μm or more at an arbitrary position of the individual layers, and an average value thereof may be calculated.

Peeling in an interface between the base 3 and the coating layer 7 may be evaluated by a peeling rate (%). The peeling rate 0% indicates a state where the base 3 and the coating layer 7 are completely adhered to each other. The peeling rate 100% indicates a state where the base 3 and the coating layer 7 are completely separated from to each other.

The peeling rate may be measured by Rockwell hardness test. For example, measurement conditions may be set as follows. A test load may be 60 kg. As to determination of peeling, exposure of the base 3 around an indentation after the Rockwell hardness test may be employed to determine occurrence of peeling. The peeling rate (%) may be calculated from equation: (number of peelings/number of measurements)×100. The number of measurements may be 10 or more.

The peeling rate may be 25% or less. This leads to high adhesion strength between the base 3 and the coating layer 7. The peeling rate may be 10% or less. The peeling rate may be 5% or less. A lower limit value of the peeling rate may be 0%. That is, the peeling rate may be 0%.

FIG. 1 illustrates a cutting insert as a non-limiting embodiment of the coated tool 1. The coated tool 1 is not limited to the cutting insert.

The coated tool 1 may include a first surface 15 (upper surface), a second surface 17 (lateral surface) adjacent to the first surface 15, and a cutting edge 19 located on at least a part of a ridgeline part of the first surface 15 and the second surface 17.

The first surface 15 may be a rake surface. The whole or a part of the first surface 15 may be the rake surface. For example, a region along the cutting edge 19 in the first surface 15 may be the rake surface.

The second surface 17 may be a flank surface. The whole or a part of the second surface 17 may be the flank surface. For example, a region along the cutting edge 19 in the second surface 17 may be the flank surface.

The cutting edge 19 may be located on a part or the whole of the ridgeline part. The cutting edge 19 is usable for machining a workpiece.

The coated tool 1 may include a through hole 21. The through hole 21 is usable for attaching a fixing screw or clamping member when holding the coated tool 1 in a holder. The through hole 21 may be formed from the first surface 15 to a surface (lower surface) located on a side opposite to the first surface 15, and the through hole 21 may also open into these surfaces. There is no problem even if the through hole 21 is configured to open into regions opposed to each other in the second surface 17.

The coated tool 1 may have a quadrangular plate shape. The shape of the coated tool 1 is not limited to the quadrangular plate shape. For example, the first surface 15 may have a triangular shape, a pentagonal shape, a hexagonal shape, or a circular shape.

The coated tool 1 is not limited to having specific dimensions. For example, a length of one side of the first surface 15 may be set to approximately 3-20 mm. A height from the first surface 15 to the surface (lower surface) on the side opposite to the first surface 15 may be set to approximately 5-20 mm.

### <Method for Manufacturing Coated Tool>

A method for manufacturing a coated tool in a non-limiting embodiment of the present disclosure is described below by exemplifying the case of manufacturing the coated tool 1.

A base 3 may be made initially when manufacturing the coated tool 1. Firstly, WC powder, Co powder, and TiC powder may be prepared as raw material powder. A proportion of the Co powder may be 4-12% by mass. A proportion of the Tic powder may be 0.5-15% by mass. The rest may be the WC powder.

TaC powder, ZrC powder, and NbC powder may be additionally prepared as raw material powder. A proportion of the TaC powder may be 0.1-5% by mass. A proportion of the ZrC powder may be 0.1-3% by mass. A proportion of the NbC powder may be 0.1-3% by mass.

Mean particle diameters of the raw material powders may be suitably selected in a range of 0.1-10 μm. The mean particle diameters of the raw material powders may be values measured by micro track method.

A molded body may be obtained by mixing the prepared raw material powders, followed by molding. Examples of molding method may include press molding, casting molding, extrusion molding, and cold isostatic pressing.

The obtained molded body may be subjected to debinding treatment and then sintering. The sintering may be carried out in a non-oxidizing atmosphere, such as vacuum, argon atmosphere, and nitrogen atmosphere. A sintering temperature may be 1450-1600° C. Sintering time may be 0.5-3 hours.

The base 3 may be obtained by sintering, followed by cooling. A cooling rate may be set to 6-20° C./min. More specifically, the cooling rate may be set to 6-15° C./min. If the cooling is carried out at the above cooling rate, it is easy to control “a” within the range of −2.5 to −0.2 GPa, and it is easy to control “b” within the range of −2.0 to 0.0 GPa. In cases where the NbC powder is used as the raw material powder and the cooling is carried out at the above cooling rate, it is easy to control “a” within the range of −1.3 to −0.5 GPa, it is easy to control “b” within the range of −0.6 to −0.2 GPa, and it is easy to maintain the ratio (a/b) of 2.1 or more.

Subsequently, a coating layer 7 may be deposited on a surface 5 of the obtained base 3 by CVD method, thereby obtaining the coated tool 1. As the coating layer 7, for example, a first layer 9, a second layer 11, and a third layer 13 may be deposited from a side of the base 3.

The first layer 9 including TiCN may be deposited as follows. Firstly, a mixed gas composed of 0.1-10% by volume of titanium tetrachloride (TiCl₄) gas, 10-60% by volume of nitrogen (N₂) gas, 0.1-15% by volume of methane (CH₄) gas, and the rest that is hydrogen (H₂) gas may be prepared as a reaction gas composition. Then, the mixed gas may be introduced into a chamber to deposit the first layer 9 by setting a temperature of 800-1100° C. and a pressure of 5-30 kPa. These deposition conditions are also applicable to the third layer 13 including TiCN.

The second layer 11 including Al₂O₃ may be deposited as follows. Firstly, a mixed gas composed of 0.5-5% by volume of aluminum trichloride (AlCl₃) gas, 0.5-3.5% by volume of hydrogen chloride (HCl) gas, 0.5-5% by volume of carbon dioxide (CO₂) gas, 0.5% by volume or less of hydrogen sulfide (H₂S) gas, and the rest that is hydrogen (H₂) gas may be prepared as a reaction gas composition. Then, the mixed gas may be introduced into the chamber to deposit the second layer 11 by setting a temperature of 930-1010° C. and a pressure of 5-10 kPa.

The third layer 13 including TiN may be deposited as follows. Firstly, a mixed gas composed of 0.1-10% by volume of titanium tetrachloride (TiCl₄) gas, 10-60% by volume of nitrogen (N₂) gas, and the rest that is hydrogen (H₂) gas may be prepared as a reaction gas composition. Then, the mixed gas may be introduced into the chamber to deposit the third layer 13 including TiN by setting a temperature of 800-1010° C. and a pressure of 10-85 kPa.

The above manufacturing method is one embodiment of the method for manufacturing the coated tool 1. Therefore, it is needless to say that the coated tool 1 is not limited to one which is manufactured by the above manufacturing method.

### <Cutting Tool>

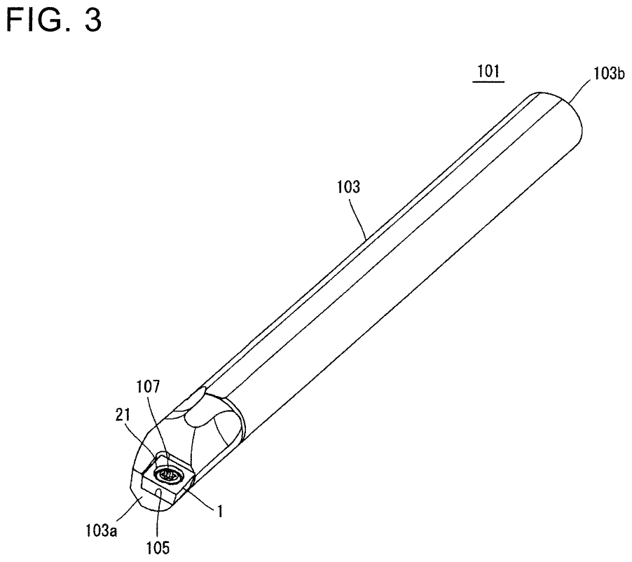

A cutting tool 101 in a non-limiting embodiment of the present disclosure is described below with reference to FIG. 3 by exemplifying the case of including the coated tool 1.

The cutting tool 101 may include a holder 103 that extends from a first end 103a toward a second end 103b and includes a pocket 105 on a side of the first end 103a, and the coated tool 1 located in the pocket 105 as in a non-limiting embodiment illustrated in FIG. 3. If the cutting tool 101 includes the coated tool 1, a stable machining can be carried out because of the high wear resistance of the coated tool 1.

The pocket 105 may be a part to which the coated tool 1 is attached. The pocket 105 may open into an outer peripheral surface of the holder 103 and an end surface on a side of the first end 103a.

The coated tool 1 may be attached to the pocket 105 so that a cutting edge 19 can be protruded outward from the holder 103. The coated tool 1 may also be attached to the pocket 105 by a fixing screw 107. That is, the coated tool 1 may be attached to the pocket 105 by inserting the fixing screw 107 into a through hole 21 of the coated tool 1, and by inserting a front end of the fixing screw 107 into a screw hole formed in the pocket 105 so as to ensure engagement between screw parts. In this case, a lower surface of the coated tool 1 may be directly contacted with the pocket 105, or alternatively, a sheet may be held between the coated tool 1 and the pocket 105.

For example, steel and cast iron are usable as a material of the holder 103. If the material of the holder 103 is steel, the holder 103 has high toughness.

The cutting tool 101 used for a so-called turning process is exemplified in the embodiment illustrated in FIG. 3. Examples of the turning process may include internal machining, external machining, and grooving process. The use of the cutting tool 101 is not limited to the turning process. For example, there is no problem even if the cutting tool 101 is used for a milling process.

While the coated tool 1 and the cutting tool 101 in the non-limiting embodiments of the present disclosure have been exemplified above, the present disclosure is not limited to the above embodiments. Needless to say, it is possible to make any arbitrary one without departing from the scope of the present disclosure.

Although the above non-limiting embodiment has described, for example, the case of applying the coated tool 1 to the cutting tool 101, the coated tool 1 is also applicable to other uses. Examples of other uses may include wear-resistant parts such as sliding parts and metal molds, digging tools, tools such as edged tools, and impact-resistant parts.

The coated tool 1 and the cutting tool 101 may have the following configurations.

(1) The coated tool is one which includes a base and a coating layer located on a surface of the base. The base includes a hard phase including W and C, a solid solution phase including W, C, and Ti, and a binding phase including an iron group metal. A residual stress of the hard phase in the base is “a,” and the “a” is in a range of −2.5 to −0.2 GPa. A residual stress of the hard phase in the surface of the base is “b,” and the “b” is in a range of −2.0 to 0.0 GPa.

(2) The “a” may be in a range of −1.3 to −0.5 GPa in the coated tool of the above (1).

(3) The “b” may be in a range of −0.6 to −0.2 GPa in the coated tool of the above (1) or (2).

(4) A ratio of the “a” to the “b” (a/b) may be 1.2 or more in any one of the coated tools of the above (1) to (3).

(5) The ratio of the “a” to the “b” (a/b) may be 2.1 or more in any one of the coated tools of the above (1) to (4).

(6) A composition of the base may include Nb in any one of the coated tools of the above (1) to (5).

(7) The base may include a β phase, and the Nb may be included in the B phase or the binding phase or both of them in the coated tool of the above (6).

(8) The coating layer may include, from a side of the base, a first layer including TiCN, a second layer including Al₂O₃, and a third layer including at least one of TiN and TiCN in any one of the coated tools of the above (1) to (7).

(9) A cutting tool can include a holder that extends from a first end toward a second end and includes a pocket on a side of the first end, and the coated tool of any one of the above (1) to (8).

Although the present disclosure is described in detail below by giving Examples, the present disclosure is not limited to the following Examples.

### EXAMPLES

### Samples Nos. 1 to 10

### <Manufacturing of Coated Tools>

Firstly, a base was manufactured. Specifically, WC powder whose mean particle diameter was 9 μm, TiC powder whose mean particle diameter was 1.5 μm, TaC powder whose mean particle diameter was 0.9 μm, ZrC powder whose mean particle diameter was 1.5 μm, Co powder whose mean particle diameter was 1.5 μm, and NbC powder whose mean particle diameter was 1.1 μm were prepared as raw material powder. These mean particle diameters of the raw material powders were values measured by micro-track method.

Subsequently, a molded body was obtained by mixing these raw material powders at individual proportions of a composition A, a composition B, or a composition C presented in Table 1, followed by press molding into a cutting tool shape (CNMG120408). The obtained molded body was subjected to debinding treatment and then sintering while keeping at a temperature of 1550° C. for one hour. Then, a base was obtained by cooling after the sintering. At that time, a cooling rate was set to conditions presented in Table 2.

Individual compositions of the hard phase, the solid solution phase, and the binding phase in the base were measured by the EDS. Measurement conditions of the EDS are as follows.

Acceleration voltage: 20 kV

Beam diameter: 12 to 15 (Counts detected by an apparatus are adjusted to 20000 or more)

The results of the measurements by the EDS showed that each of the obtained bases had the hard phase including W and C as a main component, the solid solution phase including W, C, and Ti as a main component, and the binding phase including an iron group metal (Co) as a main component. In each of the bases obtained with the composition B or C, the composition of the base included Nb, and the base included the B phase. The results of the measurement of the composition of the β phase by the EDS showed that the β phase was (W, Ti, Nb, Ta, Zr) C, and Nb was included in the β phase and the binding phase.

Subsequently, a coating layer was deposited on a surface of the obtained base by CVD method, thereby obtaining a coated tool presented in Table 2. As the coating layer, a first layer that included TiCN as a main component and had a thickness of 9 μm, a second layer that included Al₂O₃ as a main component and had a thickness of 7 μm, and a third layer that included TiN as a main component and had a thickness of 16 μm were deposited from a side of the base. The thicknesses of these layers are average values.

### Evaluation

A residual stress and a peeling rate in each of the obtained coated tools were measured. Measurement methods are described below, and the results thereof are presented in Table 2.

### (Residual Stress)

The measurement was made by sin 2ψ method using XRD. An interior of the base located 2 mm away from the surface of the base was regarded as “in the base.” Measurement conditions are as follows.
Radiation Source: CuK
Output: 50 kV, 1000 μA
Collimator diameter: 0.5 mm
Measurement method: 2D method

### (Peeling Rate)

The measurement was made by Rockwell hardness test. Measurement conditions are as follows. A test load was 60 kg. As to determination of peeling, exposure of the base around an indentation after the Rockwell hardness test was employed to determine occurrence of peeling. The peeling rate (%) was calculated from equation: (number of peelings/number of measurements)×100. The number of measurements was 20.

TABLE 1

| | A | B | C |
|---|---|---|---|
| Composition | (% by mass) | (% by mass) | (% by mass) |
| WC | 87.3 | 84 | 85.4 |
| TiC | 1.4 | 2.3 | 2.3 |
| TaC | 2.8 | 2.8 | 2.8 |
| ZrC | 1.3 | 1.3 | 1.3 |
| Co | 7.2 | 8.6 | 7.2 |
| NbC | 0 | 1 | 1 |
| Total | 100 | 100 | 100 |

TABLE 2

| | | Sintering | Residual stress (GPa) | | | |
|---|---|---|---|---|---|---|
| | | condition | | | Ratio of hard phase | Evaluation |
| | | Cooling | | Hard phase | in base to hard | result |
| Sample | | rate | Hard phase | in surface | phase in surface | Peeling rate |
| No. | Composition | (° C./min) | in base a | of base b | of base (a/b) | (%) |
| 1 | A | 10 | −1.9 | −1.5 | 1.27 | 25 |
| 2 | B | 12 | −1.3 | −0.6 | 2.17 | 10 |
| 3 | B | 14 | −0.5 | −0.2 | 2.5 | 0 |
| 4 | A | 14 | −0.2 | −0.1 | 2 | 10 |
| 5 | B | 3 | −0.1 | −0.2 | 0.5 | 75 |
| 6 | A | 5 | −1.2 | −2.4 | 0.5 | 100 |
| 7 | C | 9 | −1.5 | −0.8 | 1.88 | 25 |
| 8 | C | 7 | −1.3 | −0.65 | 2 | 10 |
| 9 | C | 6 | −0.55 | −0.25 | 2.2 | 5 |
| 10 | A | 4 | −2.6 | −2.3 | 1.13 | 60 |

The results showed that Samples Nos. 1 to 4, and 7 to 9 had higher adhesion (adhesion force) between the base and the coating layer than Samples Nos. 5, 6, and 10. Among Samples having a poor peeling rate, Sample No. 10 had a better result than Samples Nos. 5 and 6.

Samples Nos. 1 to 3, 5, and 6 were also subjected to a machining evaluation under the following conditions:
Machining Type: Turning
Cutting Speed: 150 m/min
Feed: 0.4 mm/rev
Depth of Cut: 0.5 mm
Workpiece: SCM435 ϕ200 round rod (with four grooves)
Machining State: WET

Evaluation results are shown in Table 3. The term “number of impacts until occurrence of fracture of cutting edge” in the evaluation result of Table 3 indicates the number of impacts until the cutting edge fractures during a machining process. This may also be called an intermittent performance evaluation.

TABLE 3

| | | | | | | Evaluation result |
|---|---|---|---|---|---|---|
| | | Sintering | Residual stress (GPa) | | | Number of impacts |
| | | condition | | | Ratio of hard phase | until occurrence |
| | | Cooling | | Hard phase | in base to hard | of fracture of |
| Sample | | rate | Hard phase | in surface | phase in surface | cutting edge |
| No. | Composition | (° C./min) | in base a | of base b | of base (a/b) | (times) |
| 1 | A | 10 | −1.9 | −1.5 | 1.27 | 5000 |
| 2 | B | 12 | −1.3 | −0.6 | 2.17 | 5700 |
| 3 | B | 14 | −0.5 | −0.2 | 2.5 | 8000 |
| 5 | B | 3 | −0.1 | −0.2 | 0.5 | 2000 |
| 6 | A | 5 | −1.2 | −2.4 | 0.5 | 3000 |

Compared to Samples Nos. 5 and 6, Samples Nos. 1 to 3 had enhanced wear resistance of the cutting edge, and it was possible to perform a stable machining as a cutting tool.

### DESCRIPTION OF THE REFERENCE NUMERAL

1 coated tool
3 base
surface
7 coating layer
9 first layer
11 second layer
13 third layer
first surface (upper surface)
17 second surface (lateral surface)
19 cutting edge
21 through hole
101 cutting tool
103 holder
103a first end
103b second end
105 pocket
107 fixing screw

1. A coated tool, comprising:
a base; and
a coating layer located on a surface of the base, wherein
the base comprises
a hard phase comprising W and C,
a solid solution phase comprising W, C, and Ti, and
a binding phase comprising an iron group metal,
a residual stress of the hard phase in the base is “a,” and the “a” is in a range of −2.5 to −0.2 GPa, and
a residual stress of the hard phase in the surface of the base is “b,” and the “b” is in a range of −2.0 to 0.0 GPa.

2. The coated tool according to claim 1, wherein the “a” is in a range of −1.3 to −0.5 GPa.

3. The coated tool according to claim 1, wherein the “b” is in a range of −0.6 to −0.2 GPa.

4. The coated tool according to claim 1, wherein a ratio of the “a” to the “b” (a/b) is 1.2 or more.

5. The coated tool according to claim 1, wherein a ratio of the “a” to the “b” (a/b) is 2.1 or more.

6. The coated tool according to claim 1, wherein a composition of the base comprises Nb.

7. The coated tool according to claim 6, wherein
the base comprises a β phase, and
the Nb is included in the β phase or the binding phase or both of them.

8. The coated tool according to claim 1, wherein the coating layer comprises, from a side of the base,
a first layer comprising TiCN,
a second layer comprising Al₂O₃, and
a third layer comprising at least one of TiN and TiCN.

9. A cutting tool, comprising:
a holder that extends from a first end toward a second end and comprises a pocket on a side of the first end; and
the coated tool according to claim 1, which is located in the pocket.
